(19) United States
(12) Patent Application Publication
(10) Pub. No.: US 2025/0038487 A1
(43) Pub. Date: Jan. 30, 2025

(54) INTEGRATED PHOTONIC DEVICES AND SYSTEMS WITH THERMAL DRIFT COMPENSATION

(71) Applicant: Intel Corporation, Santa Clara, CA (US)

(72) Inventors: Duanni Huang, San Jose, CA (US); Haisheng Rong, Pleasanton, CA (US); Xinru Wu, San Jose, CA (US)

(73) Assignee: Intel Corporation, Santa Clara, CA (US)

(21) Appl. No.: 18/360,999

(22) Filed: Jul. 28, 2023

(51) Int. Cl. H01S 5/40; H01S 5/00; H01S 5/06; H01S 5/125

(52) U.S. Cl. CPC H01S 5/4087; H01S 5/0085; H01S 5/0612; H01S 5/125; H01S 5/4012

(57) ABSTRACT

Integrated photonic devices, packages, and systems are disclosed. An example photonic device includes a laser device with a laser cavity having three sections. The three sections include, respectively, an active region, a waveguide, and a grating arranged along a longitudinal axis of the cavity. Materials of these three sections of the laser device are selected so that a TOC of the grating is between a TOC of the active region and a TOC of the waveguide.

### BACKGROUND

Many emerging applications such as optical interconnects (e.g., fiberoptic communications), optical computing, or light detection and ranging (LIDAR) use lasers to generate electromagnetic signals with wavelengths in the optical and microwave portions of electromagnetic spectrum (such signals referred to in the following, simply, as “light” or “optical signals”). A variety of factors can affect the cost, quality, and robustness of photonic devices that integrate light-emitting components and components used for guiding and/or manipulating light. Such photonic devices may be referred to as “integrated photonic devices.” Physical constraints, such as space/surface area, and also power consumption can impose further constraints on integrated photonic devices.

### BRIEF DESCRIPTION OF THE DRAWINGS

Embodiments will be readily understood by the following detailed description in conjunction with the accompanying drawings.

FIGS. 1-4 are schematic illustrations of example photonic devices in which laser devices with thermal drift compensation may be implemented according to various embodiments.

FIGS. 5-7 are top-down views of example laser cavities with thermal drift compensation according to various embodiments.

FIG. 8 is a top view of a wafer and dies that may be included in a photonic device with thermal drift compensation, according to an embodiment.

FIG. 9 is a side, cross-sectional view of an example microelectronic package that may include one or more photonic devices with thermal drift compensation, according to an embodiment.

FIG. 10 is a block diagram of an example computing device that may include one or more photonic devices with thermal drift compensation, according to an embodiment.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating photonic devices with thermal drift compensation proposed herein, it might be useful to first understand phenomena that may come into play in some systems where photonic devices may be used. The following foundational information may be viewed as a basis from which the present disclosure may be properly explained. Such information is offered for purposes of explanation only and, accordingly, should not be construed in any way to limit the broad scope of the present disclosure and its potential applications.

Typically lasers use direct bandgap semiconductor materials such as gallium arsenide (GaAs), indium phosphide (InP), gallium nitride (GaN), or other Ill-V semiconductors (i.e., semiconductors that are based on elements of group Ill and group V of the periodic system of elements) for light emission. Compared to indirect bandgap semiconductor materials such as silicon (Si), direct bandgap semiconductors are more fit for emitting light efficiently and coherently. However, semiconductor materials that may not be the most optimal for light generation may be preferable for light transmission and manipulation, with Si being the most prominent example of such a material. For example, Si may be used to fabricate waveguides, gratings, wavelength combiners, or other components of photonic integrated circuits (PICs).

Integration of lasers with components used for light transmission and manipulation on a single die or in a single package of an integrated photonic device is desirable but can add additional complications if their effective thermo-optic coefficients (TOCs) are different. A TOC is a measure of how refractive index of a material changes with temperature, expressed as dn/dT, where dn is the change in refractive index n and dT is the change in temperature T. When different materials are used, it is often the case that their TOCs are different. For example, TOCs of GaAs and InP are, respectively, about 2.35×10⁻⁴ per Kelvin (K⁻¹) and about 2.01×10⁻⁴ K⁻¹, while a TOC of Si is about 1.86×10⁻⁴ K⁻¹. As a result, thermally induced wavelength drift of a hybrid Si/III-V component such as a distributed Bragg reflector (DBR) laser may be different from a pure Si interferometric device such as a Mach-Zehnder Interferometer (MZI) or a ring, or from other pure Si components used for light transmission and manipulation, leading to a thermal walk-off between a hybrid Si/III-V component and a pure Si component. In this context, a “pure Si component” refers to a component where Si is the main semiconductor material used, and the term “pure” is merely used to differentiate it from a hybrid component where other materials, such as Ill-V semiconductors, also play an important role. In other words, the term “pure” is not intended to express that Si used in a pure Si component has a certain level of purity in terms of its material composition. In context of photonic devices, the term “thermal drift” may refer to a thermally induced wavelength drift, which is a measure of how wavelength of light propagating through a medium changes with temperature, expressed as dλ/dT, where dλ is the change in wavelength λ. For example, a thermally induced wavelength drift of a hybrid Si/III-V DFB laser may be about 90 picometer per Kelvin (pm/K), while a thermally induced wavelength drift of an MZI or a ring may be about 65 pm/K.

One conventional approach to compensate for the difference between thermal drifts of hybrid Si/Ill-V components and pure Si components is to heat pure Si components, thus artificially increasing the thermal drift of pure Si components to keep up with the thermal drift of hybrid Si/Ill-V components. However, such an approach increases power consumption due to heating and requires an active feedback to determine how much pure Si components should be heated.

As the foregoing illustrates, compensating for the differences in thermal drift of materials used for emitting light and thermal drift of materials used to guide and manipulate light is not trivial and further improvements are needed.

Disclosed herein are integrated photonic devices, packages, and systems that aim to improve on one or more challenges described above. In particular, embodiments of the present disclosure are based on recognition that design of a laser device of an integrated photonic device may be modified in order to reduce or eliminate the differences in thermal drift of materials used for emitting light and that of materials used to guide and manipulate light, thus reducing or eliminating thermal walk-off. An example photonic device includes a laser device with a laser cavity having three sections. The three sections include, respectively, an active region, a waveguide, and a grating arranged along a longitudinal axis of the cavity. The active region may be used to emit light of a certain wavelength. The grating may be used to change the wavelength of the light emitted by the active region to another wavelength. The waveguide may be used to transmit light within the laser cavity (e.g., to transmit light between the active region and the grating) and, in some embodiments, may also be used to control the phase of the light being transmitted. Materials of these three sections of the laser device are selected so that a TOC of the grating is between a TOC of the active region and a TOC of the waveguide, which is in sharp contrast to conventional implementations of such devices where, typically, both the waveguide and the grating are made of the same material, e.g., Si, and, therefore, their TOC are the same. Providing a waveguide that is made of a material with a TOC different from that of the grating, and, in particular, making sure that a TOC of the grating is between a TOC of the active region and a TOC of the waveguide, allows bringing an effective TOC of the laser cavity to be substantially at a target value or in a target range around the target value. As used herein, an effective TOC of a laser cavity refers to a weighted average of the TOCs of different sections of the laser cavity, where the weights are based on optical path lengths (OPLs) of different sections (where, as known in the art, an OPL is a product of a physical path length that light travels through a medium and the refractive index of that medium). For example, in some embodiments, the target value for the effective TOC of the laser cavity may be the TOC of the grating, which may be useful if the light output from the laser cavity is to further traverse other components made of substantially the same material as the grating (e.g., Si). Consequently, such a laser device allows compensating for the differences in thermal drift of materials used for emitting light and thermal drift of materials used to guide and manipulate light in a manner that is relatively simple to implement and maintain and does not require additional power consumption or active feedback.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Any of the features discussed with reference to any of accompanying drawings herein may be combined with any other features to form a photonic device 100, a laser cavity 112/150, a microelectronic package 2200, or a computing device 2400, as appropriate. For convenience, the phrase “laser cavities 112” may be used to refer to a collection of laser cavities 112-1, 112-2, and so on, the phrase “modulators 122” may be used to refer to a collection of modulators 122-1, 122-2, and so on, etc. A number of elements of the drawings with same reference numerals may be shared between different drawings; for ease of discussion, a description of these elements provided with respect to one of the drawings is not repeated for the other drawings, and these elements may take the form of any of the embodiments disclosed herein. The drawings are not necessarily to scale. Although some of the drawings illustrate rectilinear structures with flat walls/surfaces and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers. There may be other defects not listed here but that are common within the field of semiconductor device fabrication and packaging. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of which laser devices with thermal drift compensation as described herein.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10%, e.g., within +/−5% or within +/−2%, of the exact orientation.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “integrated circuit (IC) package” are synonymous, as are the terms “die” and “IC die.” Furthermore, the terms “chip,” “chiplet,” “die,” and “IC die” may be used interchangeably herein.

Although certain elements may be referred to in the singular herein, such elements may include multiple sub-elements. For example, “a dielectric material” may include one or more dielectric materials or “an insulator material” may include one or more insulator materials. The terms “oxide,” “carbide,” “nitride,” etc. refer to compounds containing, respectively, oxygen, carbon, nitrogen, etc. The term “high-k dielectric” refers to a material having a higher dielectric constant than silicon oxide, while the term “low-k dielectric” refers to a material having a lower dielectric constant than silicon oxide. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. With reference to optical signals and/or devices, components and elements that operate on or using optical signals, the term “conducting” can also mean “optically conducting.” The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

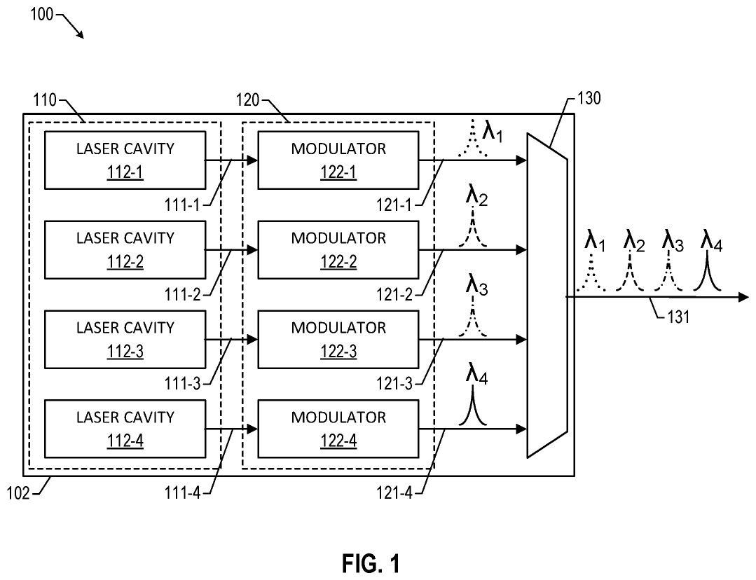

FIGS. 1-4 are schematic illustrations of example photonic devices 100 in which laser devices with thermal drift compensation may be implemented according to various embodiments.

As shown in FIG. 1, a photonic device 100 may include a laser array 110 comprising a plurality of laser cavities 112, a modulator array 120 comprising a plurality of modulators 122, and a wavelength combiner 130. Although four laser cavities 112 are illustrated in FIG. 1, in various embodiments the photonic device 100 may include any number of two or more laser cavities 112.

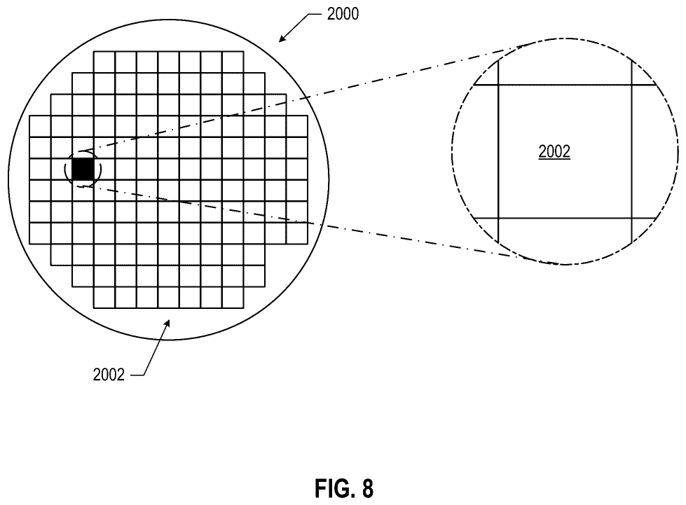

Implementations of the present disclosure may be formed or carried out on any suitable support 102, such as a substrate, a die, a wafer, or a chip. The support 102 may, e.g., be the wafer 2000 of FIG. 8, discussed below, and may be, or be included in, a die, e.g., the singulated die 2002 of FIG. 8, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group Ill-V materials, group II-VI materials (i.e., materials from groups II and VI of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. In some embodiments, the support 102 may be, or may include, a glass core. As used herein, the term “glass core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borofloat glass, lead borate glass, photosensitive glass, non-photosensitive glass, or ceramic glass. In particular, the glass core may refer to bulk glass or a solid volume of glass, as opposed to, e.g., materials that may include particles of glass, such as glass fiber reinforced polymers. Such glass materials are typically non-crystalline, often transparent, amorphous solids. In some embodiments, a glass core may be an amorphous solid glass layer. In some embodiments, a glass core may include silicon and oxygen, as well as any one or more of aluminum, boron, magnesium, calcium, barium, tin, sodium, potassium, strontium, phosphorus, zirconium, lithium, titanium, and zinc. In some embodiments, a glass core may include a material, e.g., any of the materials described above, with a weight percentage of silicon being at least about 0.5%, e.g., between about 0.5% and 50%, between about 1% and 48%, or at least about 23%. For example, if a glass core is fused silica, the weight percentage of silicon may be about 47%. In some embodiments, a glass core may include at least 23% silicon and at least 26% oxygen by weight, and, in some further embodiments, such a glass core may further include at least 5% aluminum by weight. In some embodiments, a glass core may include any of the materials described above and may further include one or more additives such as aluminum and oxygen (e.g., Al₂O₃), boron and oxygen (e.g., B₂O₃), magnesium and oxygen (e.g., MgO), calcium and oxygen (e.g., CaO), strontium and oxygen (e.g., SrO), barium and oxygen (e.g., BaO), tin and oxygen (e.g., SnO₂), sodium and oxygen (e.g., Na₂O), potassium and oxygen (e.g., K₂O), phosphorous and oxygen (e.g., P₂O₃), zirconium and oxygen (e.g., ZrO₂), lithium and oxygen (e.g., Li₂O), titanium (e.g., Ti), and zinc (Zn). Although a few examples of materials from which the support 102 may be formed are described here, any material that may serve as a foundation upon which photonic devices with thermal drift compensation as described herein may be built falls within the spirit and scope of the present disclosure.

In some embodiments, the laser cavities 112 of the laser array 110 may be implemented on a single support 102. In some embodiments, the modulators 122 and the wavelength combiner 130 may be implemented on the same support 102 as the laser cavities 112, as illustrated in FIG. 1. However, in other embodiments, one or more of the modulators 122 and/or the wavelength combiner 130 may be implemented on a different support than the support 102 with the laser cavities 112.

Each of the laser cavities 112 is configured to emit light at a certain distinct wavelength and a corresponding modulator 122 of the modulator array 120 is configured to modulate the light emitted by the laser cavity associated with the modulator 122. In some embodiments, there may be a one-to-one correspondence between the laser cavities 112 and the modulators 122 in that each laser cavity 112 is associated with one and only one modulator 122, and vice versa. In context of the present disclosure, a laser cavity 112 emitting light of a certain wavelength λ may include a laser cavity 112 emitting light in a range of wavelengths with the central wavelength of the range being the wavelength λ. For example, the laser cavity 112-1 may emit light of a wavelength λ₁ and provide it as an optical signal 111-1 at its output, the laser cavity 112-2 may emit light of a wavelength λ₂ and provide it as an optical signal 111-2 at its output, the laser cavity 112-3 may emit light of a wavelength λ₃ and provide it as an optical signal 111-3 at its output, and the laser cavity 112-4 may emit light of a wavelength λ₄ and provide it as an optical signal 111-4 at its output. In some embodiments, spacing between the wavelengths of the outputs 111 of different laser cavities 112 may be ranging from about 0.1 nanometer to about 50 nanometers, e.g., from sub-nanometer to about 30 nanometers, or between about 1 nanometer and 20 nanometers. In some embodiments, the wavelengths of different laser cavities 112 may be in the range between about 1100 nanometers and about 1700 nanometers, e.g., about 1300 nanometers or about 1550 nanometers.

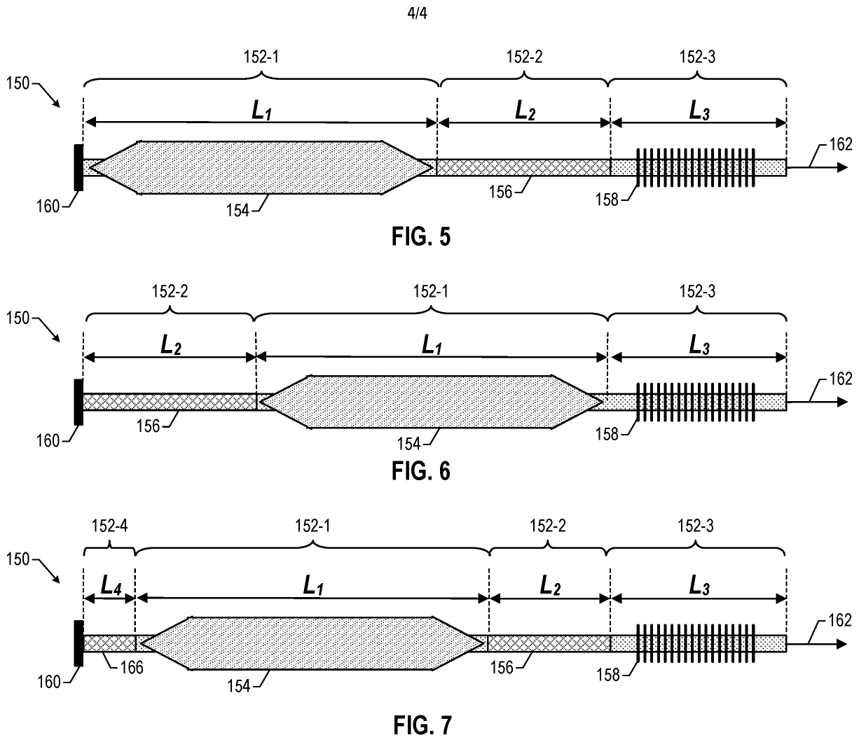

Each of the laser cavities 112 may be included in a respective laser device configured to compensate for the differences in thermal drift of materials used for emitting light and thermal drift of materials used to guide and manipulate light. Examples of such laser devices are described with reference to FIGS. 5-7. The modulators 122 may be configured to modulate data onto the light emitted by the corresponding laser cavities 112, generating respective modulator outputs 121-1 through 121-4, as shown in FIG. 1. For example, a modulator 122-1 is configured to modulate data onto the optical signal 111-1 generated by the laser cavity 112-1 to generate a modulator output 121-1, a modulator 122-2 is configured to modulate data onto the optical signal 111-2 generated by the laser cavity 112-2 to generate a modulator output 121-2, a modulator 122-3 is configured to modulate data onto the optical signal 111-3 generated by the laser cavity 112-3 to generate a modulator output 121-3, and a modulator 122-4 is configured to modulate data onto the optical signal 111-4 generated by the laser cavity 112-4 to generate a modulator output 121-4. The wavelength combiner 130 may then multiplex the modulator outputs 121 based on the optical signals 111 of the different laser cavities 112 together to generate a wavelength combiner output 131 with wavelengths λ₁-λ₄. Different ways of implementing modulators and the wavelength combiner are known in the art, all of which being within the scope of the present disclosure. For example, in some embodiments, modulators 122 may be implemented as ring modulators (in some embodiments, modulators 122 may be wavelength-selective modulators), while a wavelength combiner 130 may be implemented as a MZI.

In the photonic device 100 shown in FIG. 1, modulation is performed before wavelength combining because the modulators 122 are in the signal path between the laser cavities 112 and the wavelength combiner 130. Thus, in the photonic device 100 shown in FIG. 1, different modulators 122 are configured to receive as inputs optical signals 111 generated by their respective laser cavities 112, apply modulation to the optical signals 111 to generate respective modulator outputs 121, and the wavelength combiner 130 is configured to combine modulator outputs 121 from all of the modulators 122 to generate the wavelength combiner output 131.

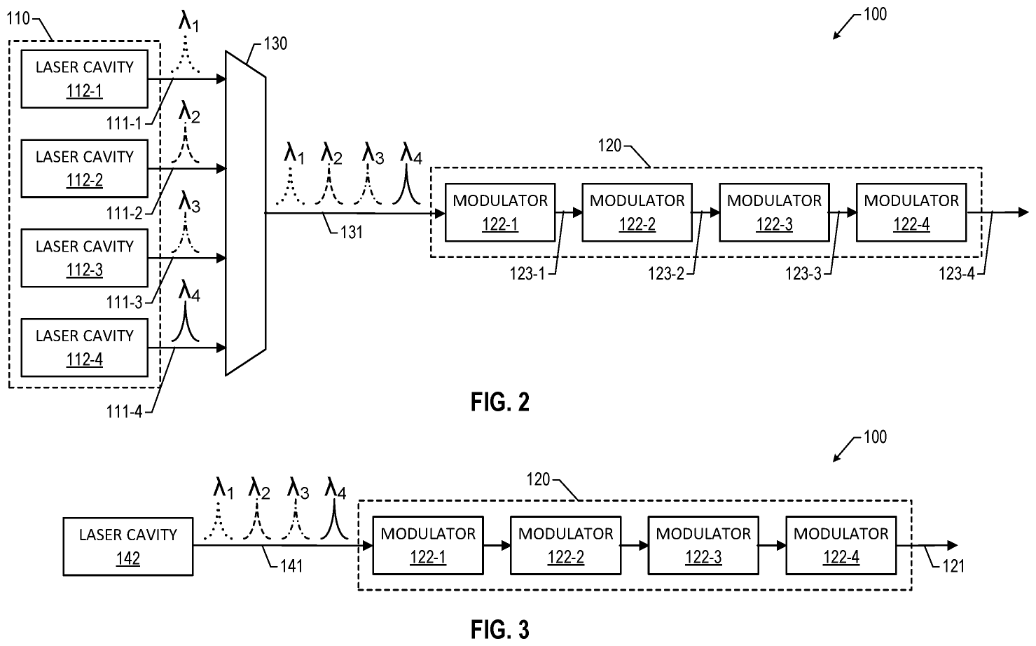

FIG. 2 illustrates a photonic device 100 that is substantially the same as that shown in FIG. 1 except that, in the photonic device 100 of FIG. 2, modulation is performed after wavelength combining (i.e., the wavelength combiner 130 is in the signal path between the laser cavities 112 and the modulators 122). Thus, in the photonic device 100 of FIG. 2, the wavelength combiner 130 first combines the outputs 111 of different laser cavities 112 to generate a wavelength combiner output 131 (i.e., the wavelength combiner output 131 does not include any modulated portions), and the modulators 122 then apply modulation to the distinct wavelengths generated by different laser cavities 112 to generate a modulator output signal 123-4 that includes a combination (e.g., a superposition) of the individual signals 121-1, 121-2, 121-3, and 121-4 as described above. To realize that the modulators 122 of the photonic device 100 of FIG. 2 may be wavelength-selective modulators, which means that each modulator 122 may receive as an input an optical signal that includes multiple central wavelengths (e.g., wavelengths λ₁-λ₄), but only apply modulation to a portion of the optical signal for which the carrier wavelength is that of the output signal 111 of the associated laser cavity 112. For example, for the photonic device 100 of FIG. 2, the modulator 121-1 may receive as an input the wavelength combiner output 131 that is a combination of the optical signals 111-1 through 111-4, apply modulation to the optical signal 111-1 to generate the modulator output 121-1, and pass the optical signals 111-2 through 111-4 without modulation; thus a modulator output 123-1 of the modulator 122-1 is a combination of the modulator output 121-1 and optical signals 111-2, 111-3, and 111-4. Then the modulator 121-2 may receive as an input the modulator output 123-1 from the modulator 121-1, apply modulation to the optical signal 111-2 of the modulator output 123-1 to generate the modulator output 121-2, and pass the optical signals 111-3 and 111-4, as well as the modulator output 121-1, without modulation; thus a modulator output 123-2 of the modulator 122-2 is a combination of the modulator output 121-1, the modulator output 121-2, and optical signals 111-3 and 111-4. Next, the modulator 121-3 may receive as an input the modulator output 123-2 from the modulator 121-2, apply modulation to the optical signal 111-3 of the modulator output 123-2 to generate the modulator output 121-3, and pass the optical signal 111-4, as well as the modulator outputs 121-1 and 121-2, without modulation; thus a modulator output 123-3 of the modulator 122-3 is a combination of the modulator outputs 121-1, 121-2, and 121-3, and the optical signal 111-4. Finally, the modulator 121-4 may receive as an input the modulator output 123-3 from the modulator 121-3, apply modulation to the optical signal 111-4 of the modulator output 123-3 to generate the modulator output 121-4, and pass the modulator outputs 121-1, 121-2, and 121-3 without modulation; thus a modulator output 123-4 of the modulator 122-4 is a combination of the modulator outputs 121-1, 121-2, 121-3, and 121-4.

FIG. 3 illustrates a photonic device 100 that is substantially the same as that shown in FIG. 2 except that, in the photonic device 100 of FIG. 3, a single laser cavity 142 is used to generate an optical signal 141 having a plurality of distinct wavelengths, e.g., wavelengths λ₁-λ₄ as described above. Thus, the laser cavity 142 may replace the plurality of laser cavities 112 of the laser array 110 of FIG. 2, and the optical signal 141 may be substantially the same as the wavelength combiner output 131 of the photonic device 100 of FIG. 2. Ways of implementing a single laser cavity that may generate different wavelengths are known in the art, all of which being within the scope of the present disclosure. For example, in some embodiments, the laser cavity 142 may include several Bragg gratings superimposed over one another, where each individual Bragg grating has a designated period that corresponds to one laser wavelength and the superimposed gratings together form a single complex grating. Because all of the wavelengths are generated from a single laser cavity 142, the wavelengths may shift together when environmental conditions and laser parameters change (e.g., bias current, temperature, etcetera), which may simplify tracking and controlling the wavelengths.

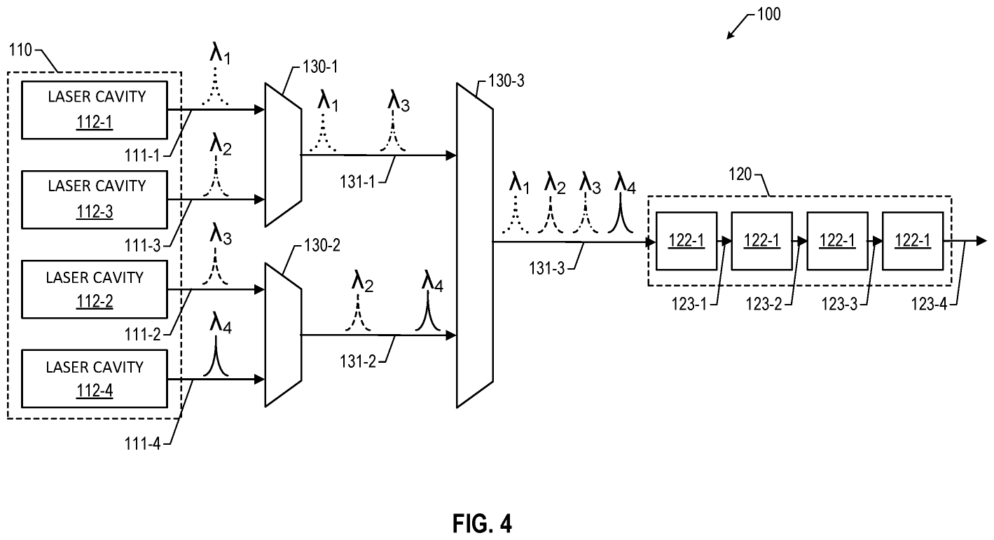

FIG. 4 illustrates a photonic device 100 that is also substantially the same as that shown in FIG. 2 except that, in the photonic device 100 of FIG. 4, instead of one wavelength combiner 130, a plurality of wavelength combiners 130 are used and the laser cavities 112 are arranged in different groups than a group shown in FIG. 2. In particular, FIG. 4 illustrates an embodiment where a first wavelength combiner 130-1 may be used to combine the optical signal 111-1 from the output of the laser cavity 112-1 (i.e., light of a wavelength λ₁) and the optical signal 111-3 from the output of the laser cavity 112-3 (i.e., light of a wavelength λ₃), thus generating a wavelength combiner output 131-1 with wavelengths λ₁ and λ₃. A second wavelength combiner 130-2 may be used to combine the optical signal 111-2 from the output of the laser cavity 112-2 (i.e., light of a wavelength λ₂) and the optical signal 111-4 from the output of the laser cavity 112-4 (i.e., light of a wavelength λ₄), thus generating a wavelength combiner output 131-2 with wavelengths λ₂ and λ₄. A third wavelength combiner 130-3 may then be used to combine the wavelength combiner outputs 131-1 and 131-2 to generate a wavelength combiner output 131-3 with wavelengths λ₁-λ₄. The wavelength combiner output 131-3 may be substantially the same as the wavelength combiner output 131 of the photonic device 100 of FIG. 2, but the implementation shown in FIG. 4 may be particularly advantageous if the wavelength combiners 130-1, 130-2, and 130-3 are MZIs, and if wavelengths λ₁-λ₄ and the free spectral range (FSR) of the MZIs are selected in a certain way. In particular, in some embodiments of the photonic device 100 of FIG. 4, the wavelength λ₂ may be a sum of the wavelength λ₁ and Δλ, where Δλ is the desired wavelength spacing for the output of the laser array 110, the wavelength λ₃ may be a sum of the wavelength λ₁ and 2*Δλ, and the wavelength λ₄ may be a sum of the wavelength λ₁ and 3*Δλ, the FSR of each of the wavelength combiners 130-1 and 130-2 may be 4*Δλ, and the FSR of the wavelength combiner 130-3 may be 2*Δλ. Such an arrangement may be particularly suitable for generating the wavelength combiner output 131-3 with wavelengths λ₁-λ₄ spaced from one another, sequentially, with the wavelength spacing Δλ.

In order to not clutter the drawings, the support 102 is not specifically shown in FIGS. 2-4 but is included in the photonic devices 100 with the same considerations as those provided for the photonic device 100 of FIG. 1.

Various arrangements of the photonic devices 100 as shown in FIGS. 1-4 do not represent an exhaustive set of photonic devices 100 in which laser devices with thermal drift compensation by means of specially designed laser cavities 112 as described herein may be implemented, but merely provide examples of such photonic devices. In particular, the number and positions of various elements shown in FIGS. 1-4 is purely illustrative and, in various other embodiments, other numbers of these elements, provided in other locations relative to one another may be used in accordance with the general architecture considerations described herein.

FIGS. 5-7 are top-down views of example laser cavities 150 with thermal drift compensation according to various embodiments. Each of the laser cavities 150 may be an example of one of the laser cavities 112 or of the laser cavity 142 of the photonic device 100.

As shown in FIG. 5, a laser cavity 150 may include three sections 152, labeled as a section 152-1, 152-2, and 152-3, extending along a longitudinal axis of the laser cavity 150 (the longitudinal axis may extend in the horizontal direction, e.g., along the light output 162, shown in FIG. 5). The first section 152-1 may include an active region 154, the second section 152-2 may include a waveguide 156, and the third section 152-3 may include a grating 158. The active region 154 is configured to emit light of a certain wavelength. The waveguide 156 may be used to transmit light within the laser cavity 150 (e.g., to transmit light between the active region 154 and the grating 158 for the embodiment of the laser cavity 150 shown in FIG. 5). In some embodiments, the waveguide 156 may also be used to control the phase of the light being transmitted. The grating 158 may be used to change the wavelength of the light emitted by the active region 154 to another wavelength. As also shown in FIG. 5, the laser cavity 150 may further include a reflective element 160 such as a mirror having or another grating, arranged at the opposite end of the laser cavity 150 compared to the grating 158. Thus, in the laser cavity 150, the active region 154 is between the reflective element 160 and the grating 158, and the grating 158 is between the waveguide 156 and a light output 152 of the laser cavity 150 of a laser device. The laser cavity 150 may be a DBR laser.

Materials of the different sections 152 of the laser cavity 150 may be selected so that a TOC of the grating 158 is between a TOC of the active region 154 and a TOC of the waveguide 156. In some embodiments, the active region 154 and the grating 158 may include different semiconductor materials (e.g., the active region 154 may include a Ill-V semiconductor such as GaAs, while the grating 158 may include a IV semiconductor such as Si).

Therefore, the TOCs of the active region 154 and the grating 158 are different. In some embodiments, the waveguide 156 may be an insulator/dielectric material, e.g., a material comprising a semiconductor material (e.g., Si) and nitrogen (N), e.g., SiN. Thus, the TOC of the waveguide 156 is different from the TOC of the active region 154 and the TOC of the grating 158. In some embodiments, the TOC of the grating 158 may be lower than the TOC of the active region 154, in which case the TOC of the waveguide 156 is lower than the TOC of the grating 158, so that the TOC of the grating 158 is between the TOC of the active region 154 and the TOC of the waveguide 156. In some such embodiments, the TOC of the waveguide 156 may be lower than about 1·10⁻⁴ K⁻¹, e.g., lower than about 0.5·10⁻⁴ K⁻¹ or lower than about 0.05·10⁻⁴ K⁻¹ or lower than about 0.005·10⁻⁴ K⁻¹, while the TOC of the active region 154 may be higher than about about 1.9×10⁻⁴ K⁻¹ or higher than about about 2.0×10⁻⁴ K⁻¹. In other embodiments, the TOC of the active region 154 may be lower than the TOC of the grating 158, in which case the TOC of the waveguide 156 is higher than the TOC of the grating 158, so that the TOC of the grating 158 is between the TOC of the active region 154 and the TOC of the waveguide 156.

Making sure that the TOC of the grating 158 is between the TOC of the active region 154 and the TOC of the waveguide 156 allows bringing an effective TOC of the laser cavity 150 to be substantially at a target value or in a target range around the target value. In some embodiments, the effective TOC of the laser cavity 150 (TOC_{LC}) may be calculated as a weighted average of the TOCs of different sections 152, with the weights being based on OPLs of different sections 152 according to the following formula:

$${TOC}_{LC} = \frac{{TOC}_{1} * {OPL}_{1} + {TOC}_{2} * {OPL}_{2} + {TOC}_{3} * {OPL}_{3}}{{OPL}_{1} + {OPL}_{2} {OPL}_{3}} ,$$

where TOC₁ and OPL₁ are, respectively, the TOC and the OPL of the first section 152-1 (e.g., of the active region 154), TOC₂ and OPL₂ are, respectively, the TOC and the OPL of the second section 152-2 (e.g., of the waveguide 156), and TOC₃ and OPL₃ are, respectively, the TOC and the OPL of the third section 152-3 (e.g., of the grating 158). The OPL₁ of the first section 152-1 may be a product of a physical length L₁ and a refractive index n₁ of the first section 152-1 (e.g., of the active region 154), the OPL₂ of the second section 152-2 may be a product of a physical length L₂ and a refractive index n₂ of the second section 152-2 (e.g., of the waveguide 156), and the OPL₃ of the third section 152-3 may be a product of a physical length L₃ and a refractive index n₃ of the third section 152-3 (e.g., of the grating 158). Thus, by carefully selecting the TOCs of the individual sections 152 in combination with their OPLs, the effective TOC of the laser cavity 150 may be made substantially equal to a target value, e.g., that of the components to which the light output 162 is provided, such as a modulator, a wavelength combiner, or any other component of a PIC in which a laser device with the laser cavity 150 is included.

Relative arrangements of the active region 154, the waveguide 156, and the grating 158 with respect to how they are arranged along the longitudinal axis of the laser cavity 150 may be different in different embodiments. For example, in the laser cavity 150 shown in FIG. 5, the waveguide 156 is between the active region 154 and the grating 158. FIG. 6 illustrates a laser cavity 150 that is substantially the same as that shown in FIG. 5 except that, in the laser cavity 150 of FIG. 6, the active region 154 is between the waveguide 156 and the grating 158.

In further embodiments, the waveguide 156 may be one of a plurality of multiple non-continuous waveguides arranged along the longitudinal axis of the laser cavity 150. For example, FIG. 7 illustrates a laser cavity 150 that is substantially the same as that shown in FIG. 5 except that, in the laser cavity 150 of FIG. 7, there is also a fourth section 152-4 with a waveguide 166 having a physical length L₄. In such an embodiment, the TOC of the grating 158 may be between the TOC of the active region 154 and a TOC of the waveguide 166, where, in various embodiments, the TOCs of the waveguides 156 and 166 may either be substantially the same or different. In some embodiments, the waveguide 156 may be between the active region 154 and the grating 158, and the active region 154 may be between the waveguide 156 and the waveguide 166, as shown in FIG. 7. While FIG. 7 illustrates only one waveguide 166 similar to the waveguide 156, in other embodiments the laser cavity 150 may include further waveguides similar to the waveguide 156 (e.g., one more waveguide may be arranged between the grating 158 and the light output 162, not specifically shown in the present drawings). In the embodiments where the laser cavity 150 includes multiple waveguides similar to the waveguide 156, the effective TOC of the laser cavity 150 may still be calculated as a weighted average of the TOCs of different sections 152, with the weights being based on OPLs of different sections 152, but now taking into account that there are more sections 152.

Arrangements with one or more laser cavities or photonic devices with thermal drift compensation as disclosed herein may be included in any suitable electronic device. FIGS. 8-10 illustrate various examples of devices and components that may include one or more laser cavities or photonic devices with thermal drift compensation as disclosed herein, e.g., any of the photonic devices 100 as shown in FIGS. 1-4, any combination of such photonic devices 100, or any of the laser cavities 150 as shown in FIGS. 5-7, or any combination of such laser cavities 150 as disclosed herein.

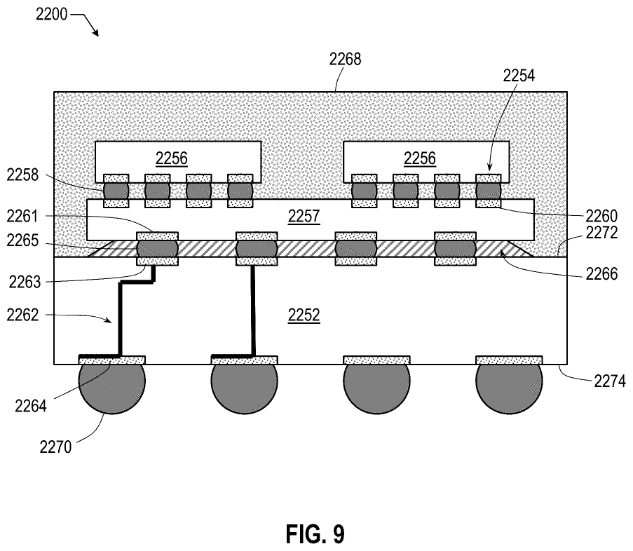

FIG. 8 illustrates top views of a wafer 2000 and dies 2002 that may include one or more laser cavities or photonic devices with thermal drift compensation in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 9. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more IC devices implementing laser cavities or photonic devices with thermal drift compensation as described herein). After the fabrication of the semiconductor product is complete (e.g., after manufacture of any embodiment of the laser cavities or photonic devices with thermal drift compensation as disclosed herein), the wafer 2000 may undergo a singulation process in which each of the dies 2002 is separated from one another to provide discrete “chips” of the semiconductor product. In particular, devices that include one or more laser cavities or photonic devices with thermal drift compensation as disclosed herein may take the form of the wafer 2000 (e.g., not singulated) or the form of the die 2002 (e.g., singulated). The die 2002 may include supporting circuitry to route electrical and/or optical signals to various components, e.g., to various laser cavities or photonic devices with thermal drift compensation, transistors, capacitors, resistors, as well as any other IC components. In some embodiments, the wafer 2000 or the die 2002 may implement or include a laser cavity with thermal drift compensation (e.g., one or more laser cavities 112 or a lase cavity 142), a photonic device with thermal drift compensation (e.g., any of the photonic devices 100), or any other suitable circuit element. Multiple ones of these devices may be combined on a single die 2002. For example, a laser array 110 formed by multiple laser cavities 112 with thermal drift compensation may be formed on a same die 2002.

FIG. 9 is a side, cross-sectional view of an example microelectronic package 2200 that may include one or more laser cavities or photonic devices with thermal drift compensation in accordance with any of the embodiments disclosed herein. In some embodiments, the microelectronic package 2200 may be a system-in-package (SiP).

The package substrate 2252 may be formed of a dielectric material (e.g., a ceramic, a buildup film, an epoxy film having filler particles therein, etc.), and may have conductive pathways 2262 extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The microelectronic package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 9 are solder bumps, but any suitable first-level interconnects 2265 may be used. In some embodiments, no interposer 2257 may be included in the microelectronic package 2200; instead, the dies 2256 may be coupled directly to the conductive contacts 2263 at the face 2272 by first-level interconnects 2265.

The microelectronic package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 9 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable.

Second-level interconnects 2270 may be coupled to the conductive contacts 2264. The second-level interconnects 2270 illustrated in FIG. 9 are solder balls (e.g., for a ball grid array arrangement), but any suitable second-level interconnects 22770 may be used (e.g., pins in a pin grid array arrangement or lands in a land grid array arrangement). The second-level interconnects 2270 may be used to couple the microelectronic package 2200 to another component, such as a circuit board (e.g., a motherboard), an interposer, or another IC package, as known in the art.

The dies 2256 may take the form of any of the embodiments of the die 2002 discussed herein (e.g., may include any of the embodiments of the IC devices implementing laser cavities or photonic devices with thermal drift compensation as disclosed herein). In embodiments in which the microelectronic package 2200 includes multiple dies 2256, the microelectronic package 2200 may be referred to as a multi-chip package (MCP). The dies 2256 may include circuitry to perform any desired functionality. In some embodiments, any of the dies 2256 may include one or more laser cavities or photonic devices with thermal drift compensation as discussed above; in some embodiments, at least some of the dies 2256 may not include any laser cavities or photonic devices with thermal drift compensation.

The microelectronic package 2200 illustrated in FIG. 9 may be a flip chip package, although other package architectures may be used. For example, the microelectronic package 2200 may be a ball grid array (BGA) package, such as an embedded wafer-level ball grid array (eWLB) package. In another example, the microelectronic package 2200 may be a wafer-level chip scale package (WLCSP) or a panel fan-out (FO) package. Although two dies 2256 are illustrated in the microelectronic package 2200 of FIG. 9, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

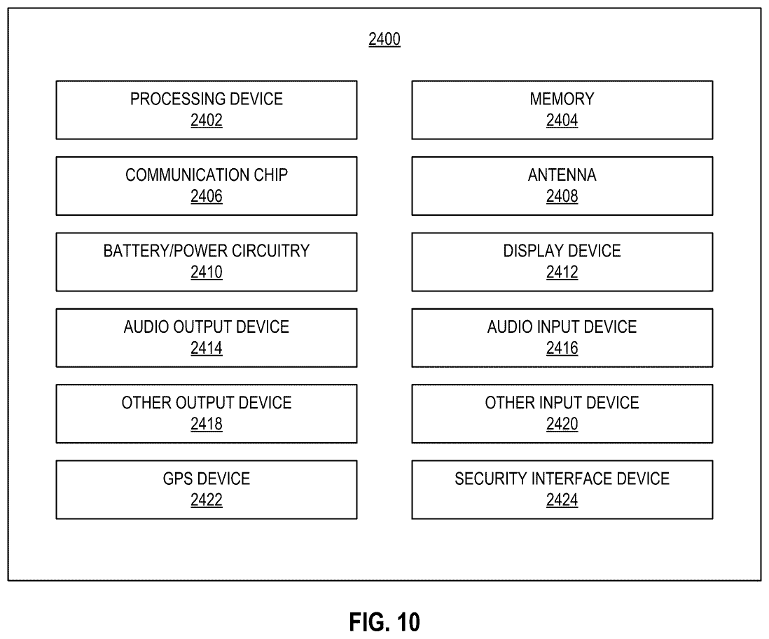

FIG. 10 is a block diagram of an example computing device 2400 that may include one or more components including laser cavities or photonic devices with thermal drift compensation in accordance with any of the embodiments disclosed herein. For example, any suitable ones of the components of the computing device 2400 may include a die (e.g., the die 2002 of FIG. 8) having one or more microelectronic packages (e.g., microelectronic packages 2200 of FIG. 9).

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide examples of various ones of the embodiments disclosed herein.

Example 1 provides a laser device that includes an active region; a waveguide; and a grating, where a TOC of the grating is between a TOC of the active region and a TOC of the waveguide and where the active region, the waveguide, and the grating extend along a longitudinal axis of a laser cavity of the laser device.

Example 2 provides the laser device according to example 1, where the waveguide is between the active region and the grating.

Example 3 provides the laser device according to example 1, where the waveguide is a first waveguide, the laser device further includes a second waveguide, and the TOC of the grating is between the TOC of the active region and a TOC of the second waveguide.

Example 4 provides the laser device according to example 3, where the TOC of the second waveguide and the TOC of the first waveguide are substantially same.

Example 5 provides the laser device according to example 3, where the TOC of the second waveguide and the TOC of the first waveguide are different.

Example 6 provides the laser device according to any one of examples 3-5, where the first waveguide is between the active region and the grating, and the active region is between the first waveguide and the second waveguide.

Example 7 provides the laser device according to any one of the preceding examples, where and the grating is between the waveguide and a light output of the laser device.

Example 8 provides the laser device according to any one of the preceding examples, further including a reflective element, and the active region is between the reflective element and the grating.

Example 9 provides the laser device according to example 8, where the reflective element is a mirror, or the grating is a first grating and the reflective element is a second grating.

Example 10 provides the laser device according to any one of the preceding examples, where the TOC of the grating is lower than the TOC of the active region.

Example 11 provides a photonic device that includes a laser cavity; and a first section, a second section, and a third section extending along a longitudinal axis of the laser cavity, where the first section includes a Ill-V semiconductor material, the second section includes a waveguide of a dielectric material, and the third section includes a semiconductor material different from the Ill-V semiconductor material.

Example 12 provides the photonic device according to example 11, where the dielectric material includes nitrogen.

Example 13 provides the photonic device according to examples 11 or 12, where the dielectric material further includes silicon.

Example 14 provides the photonic device according to any one of examples 11-13, where the semiconductor material different from the Ill-V semiconductor material is silicon.

Example 15 provides the photonic device according to any one of examples 11-14, where a TOC of the third section is between a TOC of the second section and a TOC of the first section.

Example 16 provides the photonic device according to any one of examples 11-15, where a TOC of the second section is lower than about 1·10⁻⁴ K⁻¹, e.g., lower than about 0.5·10⁻⁴ K⁻¹ or lower than about 0.05·10⁻⁴ K⁻¹ or lower than about 0.005·10⁻⁴ K⁻¹.

Example 17 provides the photonic device according to any one of examples 11-16, where the second section is between the first section and the third section.

Example 18 provides the photonic device according to any one of examples 11-17, where the photonic device is a laser.

Example 19 provides the photonic device according to any one of examples 11-18, where the first section is to emit light, and where the third section is to modify a wavelength of light emitted by the first section during operation of the photonic device.

Example 20 provides the photonic device according to any one of examples 11-19, where the third section includes a grating.

Example 21 provides the photonic device according to any one of examples 11-20, where the third section is between the second section and an output of the laser cavity.

Example 22 provides the photonic device according to example 21, further including an additional component, where the output of the laser cavity is between the third section and the additional component.

Example 23 provides the photonic device according to example 22, where the additional component is a modulator.

Example 24 provides the photonic device according to example 22, where the additional component is a wavelength combiner.

Example 25 provides the photonic device according to example 22, where the additional component is a multiplexer.

Example 26 provides the photonic device according to any one of examples 22-25, where the additional component includes the semiconductor material different from the Ill-V semiconductor material.

Example 27 provides a microelectronic assembly that includes a die and a further component coupled to the die, where the die includes a laser device according to any one of the preceding examples or a photonic device according to any one of the preceding examples.

Example 28 provides the microelectronic assembly according to example 27, where the further component is one of a package substrate, a circuit board, an interposer, or another die.

Example 29 provides the microelectronic assembly according to examples 27 or 28, further including one or more interconnects to couple the further component to the die.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A laser device, comprising:
an active region;
a waveguide; and
a grating,
wherein a thermo-optic coefficient (TOC) of the grating is between a TOC of the active region and a TOC of the waveguide.

2. The laser device according to claim 1, wherein the waveguide is between the active region and the grating.

3. The laser device according to claim 1, wherein the waveguide is a first waveguide, the laser device further includes a second waveguide, and the TOC of the grating is between the TOC of the active region and a TOC of the second waveguide.

4. The laser device according to claim 3, wherein the TOC of the second waveguide and the TOC of the first waveguide are substantially same.

5. The laser device according to claim 3, wherein the TOC of the second waveguide and the TOC of the first waveguide are different.

6. The laser device according to claim 3, wherein the first waveguide is between the active region and the grating, and the active region is between the first waveguide and the second waveguide.

7. The laser device according to claim 1, wherein and the grating is between the waveguide and a light output of the laser device.

8. The laser device according to claim 1, further comprising a reflective element, and the active region is between the reflective element and the grating.

9. The laser device according to claim 8, wherein:
the reflective element is a mirror, or
the grating is a first grating, and the reflective element is a second grating.

10. The laser device according to claim 1, wherein the TOC of the grating is lower than the TOC of the active region.

11. A photonic device, comprising:
a laser cavity; and
a first section, a second section, and a third section extending along a longitudinal axis of the laser cavity,
wherein:
the first section includes a Ill-V semiconductor material,
the second section includes a waveguide of a dielectric material, and
the third section includes a semiconductor material different from the Ill-V semiconductor material.

12. The photonic device according to claim 11, wherein the dielectric material includes nitrogen.

13. The photonic device according to claim 11, wherein the dielectric material further includes silicon.

14. The photonic device according to claim 11, wherein the semiconductor material different from the Ill-V semiconductor material is silicon.

15. The photonic device according to claim 11, wherein a thermo-optic coefficient (TOC) of the third section is between a TOC of the second section and a TOC of the first section.

16. The photonic device according to claim 11, wherein a thermo-optic coefficient (TOC) of the second section is lower than about 1·10⁻¹ K⁻¹.

17. The photonic device according to claim 11, wherein the third section is to modify a wavelength or a phase of light emitted by the first section during operation of the photonic device.

18. The photonic device according to claim 11, further comprising an additional component, wherein:
the third section is between the second section and an output of the laser cavity,
the output of the laser cavity is between the third section and the additional component,
the additional component is one of a modulator, a wavelength combiner, or a multiplexer, and
the additional component includes the semiconductor material different from the Ill-V semiconductor material.

19. A microelectronic assembly, comprising:
a die; and
a further component coupled to the die, wherein the die includes a laser cavity comprising a first section, a second section, and a third section extending along a longitudinal axis of the laser cavity,
wherein:
the first section includes a first material to emit light, the first material having a first thermo-optic coefficient (TOC),
the second section includes a waveguide of a second material to guide the light, the second material having a second TOC,
the third section includes a structure of a third material to modify a wavelength or a phase of the light, the third material having a third TOC, and
the third TOC is between the second TOC and the first TOC.

20. The microelectronic assembly according to claim 19, wherein the further component is one of a package substrate, a circuit board, an interposer, or another die.
